(19) United States
(12) Patent Application Publication
(10) Pub. No.: US 2025/0370196 A1
(43) Pub. Date: Dec. 4, 2025

(54) DEVICE COMPRISING AN OPTO-ELECTRONIC INTEGRATED DEVICE AND STACKED INTEGRATED DEVICES

(71) Applicant: QUALCOMM Incorporated, San Diego, CA (US)

(72) Inventors: Je-Hsiung LAN, San Diego, CA (US); Jonghae KIM, San Diego, CA (US); Ranadeep DUTTA, Del Mar, CA (US)

(21) Appl. No.: 18/680,526

(22) Filed: May 31, 2024

(51) Int. Cl. G02B 6/42; G02B 6/43

(52) U.S. Cl. CPC G02B 6/4238; G02B 6/4204; G02B 6/43

(57) ABSTRACT

A device comprising a substrate; an opto-electronic integrated device coupled to the substrate; a first integrated device coupled to the substrate through a first plurality of solder interconnects; and a second integrated device coupled to the first integrated device through a second plurality of solder interconnects.

### FIELD

Various features relate to an opto-electronic integrated device and integrated devices.

BACKGROUND

A package may include a substrate, an opto-electronic integrated device and integrated devices. These components are coupled together to provide a package that may perform various functions. The performance of a package and its components may depend on many factors. There is an ongoing need to provide packages that provide improved performances. Moreover, there is an ongoing need to provide a package that includes a more compact form factor so that the package may be implemented in smaller devices.

### SUMMARY

Various features relate to an opto-electronic integrated device and integrated devices.

One example provides a device comprising a substrate; an opto-electronic integrated device coupled to the substrate; a first integrated device coupled to the substrate through a first plurality of solder interconnects; and a second integrated device coupled to the first integrated device through a second plurality of solder interconnects.

Another example provides a device comprising a substrate; an opto-electronic integrated device coupled to the substrate; and a group of integrated devices. The group of integrated devices comprising a first integrated device; a first encapsulation layer at least partially encapsulating the first integrated device; a second integrated device coupled to the first integrated device, wherein the second integrated device vertically overlaps with the first integrated device; and a second encapsulation layer at least partially encapsulating the second integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary package comprising an opto-electronic integrated device.

FIG. 2 illustrates a cross sectional profile view of an exemplary package comprising an opto-electronic integrated device.

FIG. 3 illustrates a cross sectional profile view of an exemplary package comprising an opto-electronic integrated device.

FIG. 4 illustrates a cross sectional profile view of an exemplary package comprising an opto-electronic integrated device.

FIGS. 5A-5B illustrate an exemplary sequence for fabricating a package comprising an opto-electronic integrated device.

FIGS. 6A-6D illustrate an exemplary sequence for fabricating a stack of integrated devices.

FIGS. 7A-7C illustrate an exemplary sequence for fabricating a package comprising an opto-electronic integrated device and a group of integrated devices.

FIG. 8 illustrates an exemplary flow diagram of a method for fabricating a package comprising an opto-electronic integrated device and a group of integrated devices.

FIGS. 9A-9B illustrate an exemplary sequence for fabricating a metallization portion.

FIG. 10 illustrates an exemplary flow chart of a method for fabricating a metallization portion.

FIG. 11 illustrates various electronic devices that may integrate a die, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device comprising a substrate; an opto-electronic integrated device coupled to the substrate; and a group of integrated devices. The group of integrated devices comprising a first integrated device; a first encapsulation layer at least partially encapsulating the first integrated device; a second integrated device coupled to the first integrated device, wherein the second integrated device vertically overlaps with the first integrated device; and a second encapsulation layer at least partially encapsulating the second integrated device. The use of integrated devices that vertically overlap, may help provide a package with a compact form, which allows the package to be implemented in smaller devices.

### Exemplary Package Comprising an Opto-Electronic Integrated Device and Stacked Integrated Devices

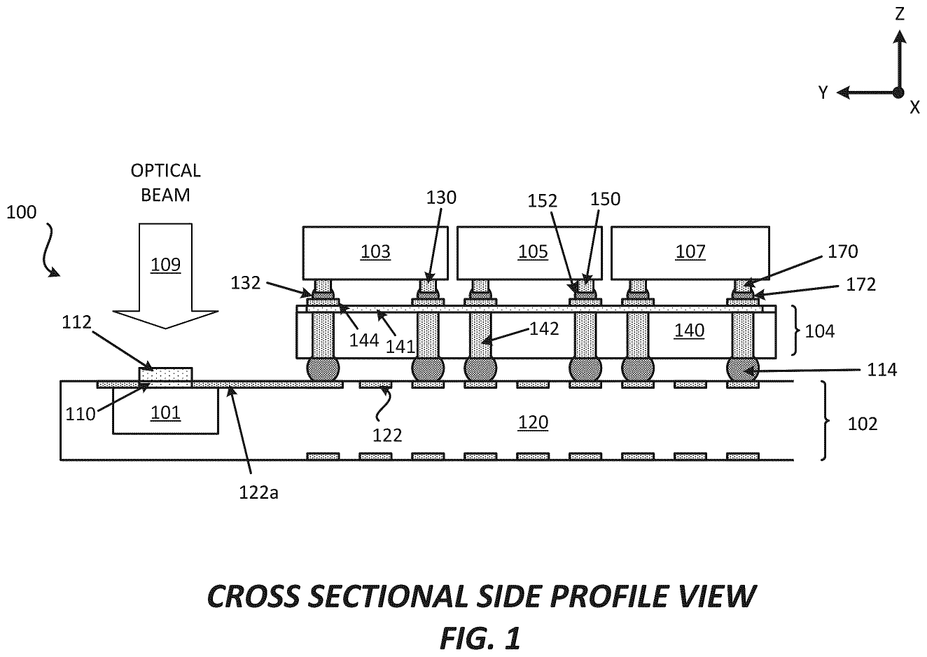

FIG. 1 illustrates a cross sectional profile view of a package 100 that includes an opto-electronic integrated device and stacked integrated devices. The package 100 includes an opto-electronic integrated device 101, a package substrate 102, an integrated device 103, an integrated device 104, an integrated device 105 and an integrated device 107. The integrated device 103, the integrated device 104, the integrated device 105 and/or the integrated device 107 may be part of a group of integrated devices.

The package substrate 102 includes at least one dielectric layer 120 and a plurality of interconnects 122. The package substrate 102 may be a laminated substrate (e.g., cored substrate, coreless substrate). The plurality of interconnects 122 include an interconnect 122a. The opto-electronic integrated device 101 is located at least partially in the package substrate 102. For example, the opto-electronic integrated device 101 is located in a cavity of the package substrate 102. The opto-electronic integrated device 101 may be coupled to and/or embedded in the package substrate 102 through an adhesive (not shown). Some of the interconnects from the plurality of interconnects 122 may be coupled to the opto-electronic integrated device 101. For example, the interconnect 122a may be coupled to the opto-electronic integrated device 101. The opto-electronic integrated device 101 may include a layer 110. The layer 110 may include indium tin oxide (ITO) that is located on a surface of the opto-electronic integrated device 101. FIG. 1 illustrates the opto-electronic integrated device 101 at least partially embedded in the package substrate 102. In some implementations, the opto-electronic integrated device 101 is not embedded the package substrate 102. In some implementations, the opto-electronic integrated device 101 may be coupled to a surface of the package substrate 102. The opto-electronic integrated device 101 may include a front side and back side. The front side of the opto-electronic integrated device 101 may face in a direction that is away from the package substrate 102. In some implementations, the front side of the opto-electronic integrated device 101 may be a side that includes the layer 110.

A lens array 112 is coupled to the opto-electronic integrated device 101. The lens array 112 may be a micro lens array (MLA). The lens array 112 may be coupled to the layer 110 of the opto-electronic integrated device 101. In some implementations, the lens array 112 may be coupled to the layer 110 of the opto-electronic integrated device 101 through a refractive index matching layer. Thus, in some implementations, one or more refractive index matching layers may be located between the lens array 112 and the layer 110. In some implementations, the refractive index matching layer may be part of the lens array 112. The lens array 112 and the layer 110 may be configured such that an optical beam 109 may travel through the lens array 112 and the layer 110 of the opto-electronic integrated device 101. In some implementations, the optical beam 109 may travel through an optical fiber (not shown) that is coupled to and/or directed towards the lens array 112 and/or the opto-electronic integrated device 101. The optical beam 109 may be a collimated beam. The opto-electronic integrated device 101 is configured such that an optical beam may enter and/or exit through the front side of the opto-electronic integrated device 101.

An opto-electronic integrated device (e.g., 101) may be configured (i) to convert optical signal/energy into electrical signal/energy, and/or (ii) to convert electrical signal/energy into optical signal/energy. For example, a signal may be received as an optical signal (e.g., optical beam) and may be converted to an electrical signal. Similarly, a signal may be received as an electrical signal and may be converted to an optical signal. An opto-electronic integrated device may send a signal as an optical signal and/or an electrical signal. An opto-electronic integrated device may receive a signal as an optical signal and/or an electrical signal.

The integrated device 104, the integrated device 103, the integrated device 105 and/or the integrated device 107 may be an example of a configuration and/or an arrangement of stacked integrated devices. The integrated device 104 may be coupled to the package substrate 102 through a plurality of solder interconnects 114. The integrated device 103 may be coupled to the integrated device 104 through a plurality of pillar interconnects 130 and/or a plurality of solder interconnects 132. The integrated device 105 may be coupled to the integrated device 104 through a plurality of pillar interconnects 150 and/or a plurality of solder interconnects 152. The integrated device 107 may be coupled to the integrated device 104 through a plurality of pillar interconnects 170 and/or a plurality of solder interconnects 172. The integrated device 104 is located between the integrated device 103 and the package substrate 102. The integrated device 104 is located between the integrated device 105 and the package substrate 102. The integrated device 104 is located between the integrated device 107 and the package substrate 102. The integrated device 103 is located laterally to the integrated device 105 and/or the integrated device 107. The integrated device 105 is located laterally to the integrated device 103 and/or the integrated device 107 Thus, the integrated device 103, the integrated device 105 and/or the integrated device 107 may be located side by side to each other.

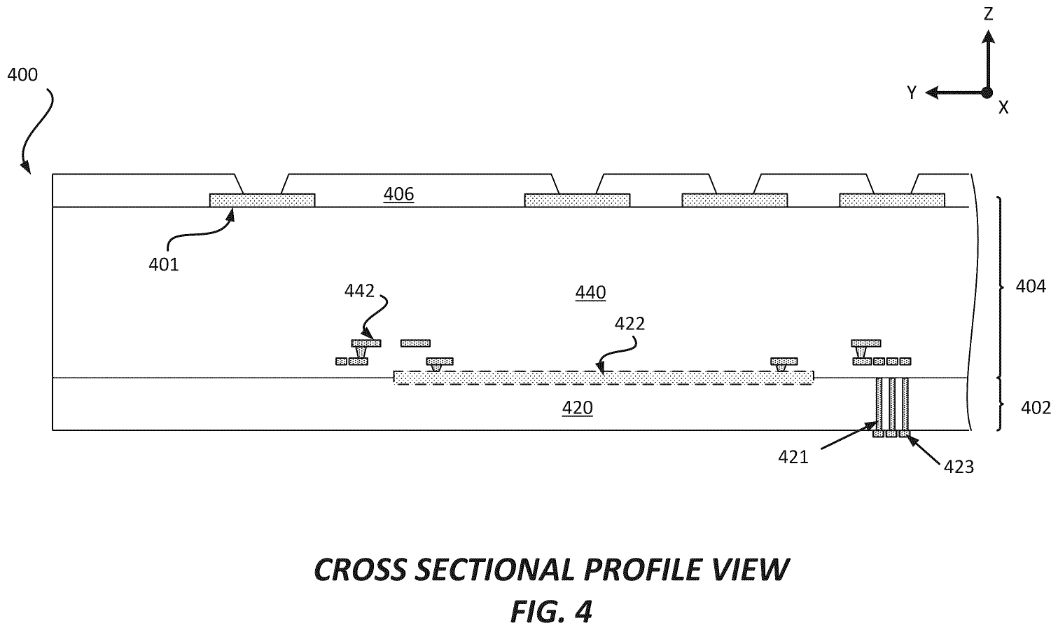

The integrated device 104 include a die substrate 140, an active region 141, a plurality of through substrate vias 142, and a plurality of interconnects 144. The integrated device 104 may include a front side and back side. The front side of the integrated device 104 may include a side that includes the plurality of interconnects 144. The plurality of interconnects 144 may include a plurality of die interconnects and/or a plurality of pad interconnects. The plurality of interconnects 144 may include one or more metal layers (e.g., one or more die metal layers). The back side of the integrated device 104 may include the side that includes the die substrate 140. The plurality of through substrate vias 142 may extend through the die substrate 140. The plurality of through substrate vias 142 may be configured to be electrically coupled to the active region 141 and/or the plurality of interconnects 144. Although not shown, the integrated device 104 may include metallization interconnects (e.g., back side interconnects) coupled to the back side of the die substrate 140. Such back side interconnects may be coupled to the plurality of through substrate vias 142. A detailed example of an integrated device is illustrated and described below in FIG. 4. In some implementations, the integrated device (and/or a variation) illustrated in FIG. 4 may represent the integrated device 103, the integrated device 104, the integrated device 105 and/or the integrated device 107.

In some implementations, the integrated device 103 may be configured as a low noise amplifier (LNA). In some implementations, the integrated device 105 may be configured as a power amplifier (PA). In some implementations, the integrated device 107 may be configured as a switch (SW) (e.g., transmit and/or receive switch). In some implementations, the integrated device 104 may be configured as a transceiver (e.g., transmitter and/or receiver). The integrated device 104 may include a silicon Complementary Metal-Oxide-Semiconductor (CMOS).

A front side of the integrated device 103 may face in a direction of the integrated device 104 and/or the package substrate 102. A front side of the integrated device 105 may face in a direction of the integrated device 104 and/or the package substrate 102. A front side of the integrated device 107 may face in a direction of the integrated device 104 and/or the package substrate 102. The front side of the integrated device 104 may face in a direction of the integrated device 103, the integrated device 105 and/or the integrated device 107. A back side of the integrated device 104 may face in a direction of the package substrate 102.

The integrated device 103, the integrated device 105, and/or the integrated device 107 may be configured to be electrically coupled to the package substrate 102 through the integrated device 104. In some implementations, an electrical path between the integrated device 103 and the package substrate 102 may include (i) at least one pillar interconnect from the plurality of pillar interconnects 130, (ii) at least one solder interconnect from the plurality of solder interconnects 132, (iii) the integrated device 104 (e.g., at least one interconnect and/or at least one through substrate via from the integrated device 104) and/or (iv) at least one solder interconnect from the plurality of solder interconnects 114. In some implementations, an electrical path between the integrated device 105 and the package substrate 102 may include (i) at least one pillar interconnect from the plurality of pillar interconnects 150, (ii) at least one solder interconnect from the plurality of solder interconnects 152, (iii) the integrated device 104 (e.g., at least one interconnect and/or at least one through substrate via from the integrated device 104) and/or (iv) at least one solder interconnect from the plurality of solder interconnects 114. An electrical path between the integrated device 107 and the package substrate 102 may include (i) at least one pillar interconnect from the plurality of pillar interconnects 170, (ii) at least one solder interconnect from the plurality of solder interconnects 172, (iii) the integrated device 104 (e.g., at least one interconnect and/or at least one through substrate via from the integrated device 104) and/or (iv) at least one solder interconnect from the plurality of solder interconnects 114.

In some implementations, an electrical path between the integrated device 103 and the integrated device 105 may include (i) at least one pillar interconnect from the plurality of pillar interconnects 130, (ii) at least one solder interconnect from the plurality of solder interconnects 132, (iii) the integrated device 104, (iv) at least one solder interconnect from the plurality of solder interconnects 152 and/or (v) at least one pillar interconnect from the plurality of pillar interconnects 150.

In some implementations, an electrical path between the integrated device 103 and the integrated device 107 may include (i) at least one pillar interconnect from the plurality of pillar interconnects 130, (ii) at least solder interconnect from the plurality of solder interconnects 132, (iii) the integrated device 104, (iv) at least one solder interconnect from the plurality of solder interconnects 172 and/or (v) at least one pillar interconnect from the plurality of pillar interconnects 170.

In some implementations, an electrical path between the integrated device 105 and the integrated device 107 may include (i) at least one pillar interconnect from the plurality of pillar interconnects 150, (ii) at least one solder interconnect from the plurality of solder interconnects 152, (iii) the integrated device 104, (iv) at least one solder interconnect from the plurality of solder interconnects 172 and/or (v) at least one pillar interconnect from the plurality of pillar interconnects 170.

The integrated device 103, the integrated device 105, and/or the integrated device 107 may be configured to be electrically coupled to the opto-electronic integrated device 101 through the integrated device 104 and the package substrate 102. The integrated device 104 is configured to be electrically coupled to the opto-electronic integrated device 101 through the package substrate 102 (e.g., through interconnects from the plurality of interconnects 122 of the package substrate 102). In some implementations, an electrical path between the integrated device 104 and the opto-electronic integrated device 101 may include (i) at least one solder interconnect from the plurality of solder interconnects 114 and (ii) at least one interconnect from the plurality of interconnects 122 from the package substrate 102.

The configuration and/or arrangement of the stacked integrated devices that includes the integrated device 104, the integrated device 103, the integrated device 105 and/or the integrated device 107, illustrates an example of a configuration and/or arrangement that helps provide a package that has a more compact form package. For example, the package 100 may have a smaller footprint and/or smaller lateral size. This allows the package to be implemented in smaller devices. In addition, some of the components may be located closer to each other, shortening the electrical paths for signals between at least some of the components. This may help improve the performance of the integrated devices and/or the package.

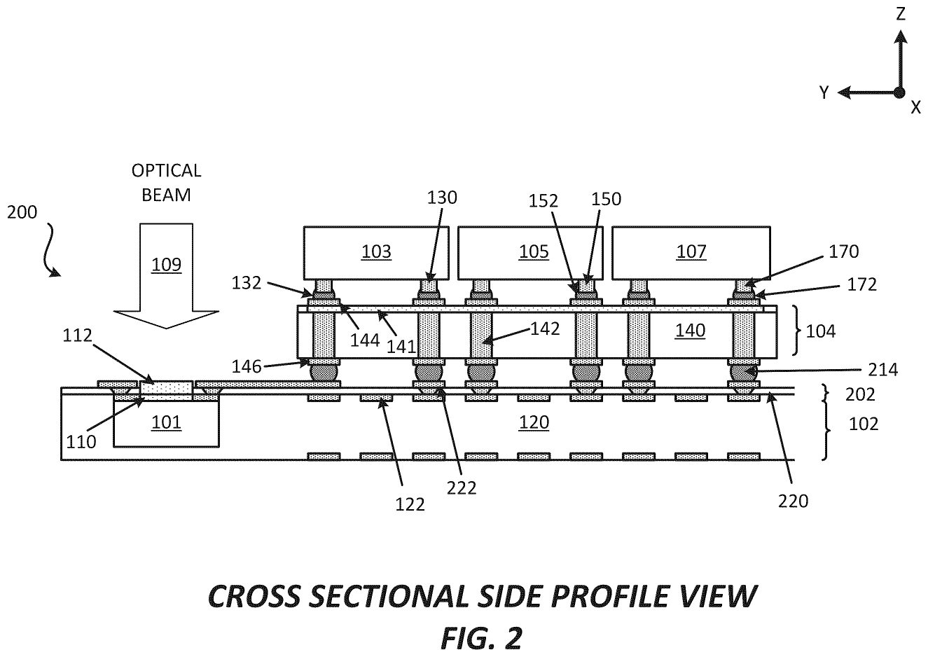

FIG. 2 illustrates a cross sectional profile view of a package 200 that includes an opto-electronic integrated device. The package 200 of FIG. 2 is similar to the package 100 of FIG. 1, and includes similar components that are arranged in a similar manner as the package 100. The package 200 includes an opto-electronic integrated device 101, a package substrate 102, a metallization portion 202, an integrated device 103, an integrated device 104, an integrated device 105 and an integrated device 107.

The package substrate 102 includes at least one dielectric layer 120 and a plurality of interconnects 122. The package substrate 102 may be a laminated substrate (e.g., cored substrate, coreless substrate). The plurality of interconnects 122 include an interconnect 122a. The metallization portion 202 includes at least one dielectric layer 220 and a plurality of metallization interconnects 222. The plurality of metallization interconnects 222 may include one or more metal layers. The metallization portion 202 is coupled to the package substrate 102. The metallization portion 202 may be formed over a first surface of the package substrate 102. The plurality of metallization interconnects 222 are coupled to the plurality of interconnects 122. The plurality of metallization interconnects 222 are coupled to the opto-electronic integrated device 101. In some implementations, the at least one dielectric layer 220 may include a same material as the at least one dielectric layer 120. In some implementations, the at least one dielectric layer 220 may include a different material from the at least one dielectric layer 120. The at least one dielectric layer 220 may include prepreg and/or polyimide. In some implementations, the metallization portion 202 may be a metallization portion of the package substrate 102. Thus, in some implementations, the metallization portion 202 may be considered part of the package substrate 102. Thus, in some implementations, the at least one dielectric layer 220 and the plurality of metallization interconnects 222 may be considered part of the package substrate 102. The metallization portion 202 may be a redistribution portion.

The opto-electronic integrated device 101 is located at least partially in the package substrate 102. For example, the opto-electronic integrated device 101 is located in a cavity of the package substrate 102. The opto-electronic integrated device 101 may be coupled to and/or embedded in the package substrate 102 through an adhesive (not shown). The opto-electronic integrated device 101 may include a layer 110. The layer 110 may include indium tin oxide (ITO) that is located on a surface of the opto-electronic integrated device 101. A lens array 112 is coupled to the opto-electronic integrated device 101. The lens array 112 may be a micro lens array (MLA). The lens array 112 may be coupled to the layer 110 of the opto-electronic integrated device 101. In some implementations, the lens array 112 may be coupled to the layer 110 of the opto-electronic integrated device 101 through a refractive index matching layer. Thus, in some implementations, one or more refractive index matching layer may be located between the lens array 112 and the layer 110. In some implementations, the refractive index matching layer may be part of the lens array 112. The lens array 112 and the opto-electronic integrated device 101 is configured such that an optical beam 109 may travel through the lens array 112 and the layer 110 of the opto-electronic integrated device 101. In some implementations, the optical beam 109 may travel through an optical fiber (not shown) that is coupled to and/or directed towards the lens array 112 and/or the opto-electronic integrated device 101. The optical beam 109 may be a collimated beam. An optical beam may be configured to travel through the front side of the opto-electronic integrated device 101.

The integrated device 104, the integrated device 103, the integrated device 105 and/or the integrated device 107 may be an example of a configuration and/or an arrangement of stacked integrated devices. The integrated device 104 may be coupled to the metallization portion 202 through a plurality of solder interconnects 214. The integrated device 103 may be coupled to the integrated device 104 through a plurality of pillar interconnects 130 and/or a plurality of solder interconnects 132. The integrated device 105 may be coupled to the integrated device 104 through a plurality of pillar interconnects 150 and/or a plurality of solder interconnects 152. The integrated device 107 may be coupled to the integrated device 104 through a plurality of pillar interconnects 170 and/or a plurality of solder interconnects 172. The integrated device 104 is located between (i) the integrated device 103 and (ii) the metallization portion 202 and/or the package substrate 102. The integrated device 104 is located between (i) the integrated device 105 and (ii) the metallization portion 202 and/or the package substrate 102. The integrated device 104 is located between (i) the integrated device 107 and (ii) the metallization portion 202 and/or the package substrate 102. The integrated device 103 is located laterally to the integrated device 105 and/or the integrated device 107. The integrated device 105 is located laterally to the integrated device 103 and/or the integrated device 107 Thus, the integrated device 103, the integrated device 105 and/or the integrated device 107 may be located side by side to each other.

The integrated device 104 is coupled to the metallization portion 202 through a plurality of solder interconnects 214. For example, the integrated device 104 may be coupled to the plurality of metallization interconnects 222 of the metallization portion 202. The integrated device 104 may be coupled to the package substrate 102 through the plurality of solder interconnects 214 and the metallization portion 202. The integrated device 104 is configured to be electrically coupled to the opto-electronic integrated device 101 through the metallization portion 202. In some implementations, an electrical path between the integrated device 104 and the opto-electronic integrated device 101 may include (i) at least one solder interconnect from the plurality of solder interconnects 214 and (ii) at least one metallization interconnect from the plurality of metallization interconnects 222.

The integrated device 103, the integrated device 105, and/or the integrated device 107 may be configured to be electrically coupled to the metallization portion 202 and/or the package substrate 102 through the integrated device 104. In some implementations, an electrical path between the integrated device 103 and the package substrate 102 may include (i) at least one pillar interconnect from the plurality of pillar interconnects 130, (ii) at least one solder interconnect from the plurality of solder interconnects 132, (iii) the integrated device 104 (e.g., at least one interconnect and/or at least one through substrate via from the integrated device 104), (iv) at least one solder interconnect from the plurality of solder interconnects 214 and/or (v) at least one metallization interconnect from the plurality of metallization interconnects 222. In some implementations, an electrical path between the integrated device 105 and the package substrate 102 may include (i) at least one pillar interconnect from the plurality of pillar interconnects 150, (ii) at least one solder interconnect from the plurality of solder interconnects 152, (iii) the integrated device 104 (e.g., at least one interconnect and/or at least one through substrate via from the integrated device 104), (iv) at least one solder interconnect from the plurality of solder interconnects 214 and/or (v) at least one metallization interconnect from the plurality of metallization interconnects 222. An electrical path between the integrated device 107 and the package substrate 102 may include (i) at least one pillar interconnect from the plurality of pillar interconnects 170, (ii) at least one solder interconnect from the plurality of solder interconnects 172, (iii) the integrated device 104 (e.g., at least one interconnect and/or at least one through substrate via from the integrated device 104, (iv) at least one solder interconnect from the plurality of solder interconnects 214 and/or (v) at least one metallization interconnect from the plurality of metallization interconnects 222.

The integrated device 103, the integrated device 105, and/or the integrated device 107 may be configured to be electrically coupled to the opto-electronic integrated device 101 through the integrated device 104 and the metallization portion 202. The integrated device 104 is configured to be electrically coupled to the opto-electronic integrated device 101 through the metallization portion 202 (e.g., through metallization interconnects from the plurality of metallization interconnects 222 of the metallization portion 202).

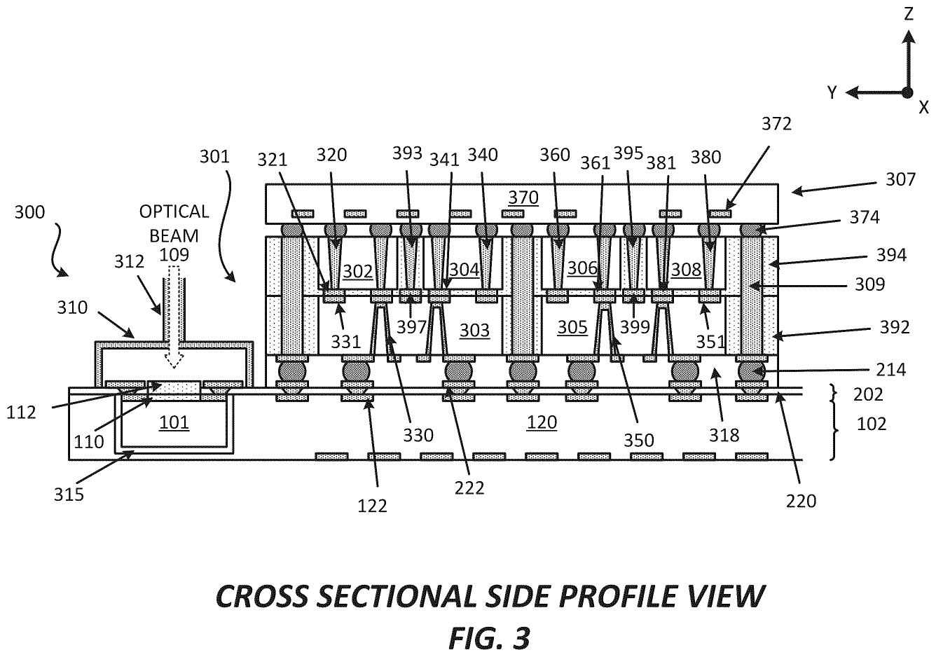

FIG. 3 illustrates a cross sectional profile view of a package 300 that includes an opto-electronic integrated device and stacked integrated devices. The package 300 includes an opto-electronic integrated device 101, a package substrate 102, a metallization portion 202, a package 301 and a substrate antenna 307.

The package substrate 102 includes at least one dielectric layer 120 and a plurality of interconnects 122. The package substrate 102 may be a laminated substrate (e.g., cored substrate, coreless substrate). The plurality of interconnects 122 include an interconnect 122a. The metallization portion 202 includes at least one dielectric layer 220 and a plurality of metallization interconnects 222. The plurality of metallization interconnects 222 may include one or more metal layers. The metallization portion 202 is coupled to the package substrate 102. The metallization portion 202 may be formed over a first surface of the package substrate 102. The plurality of metallization interconnects 222 are coupled to the plurality of interconnects 122. The plurality of metallization interconnects 222 are coupled to the opto-electronic integrated device 101. In some implementations, the at least one dielectric layer 220 may include a same material as the at least one dielectric layer 120. In some implementations, the at least one dielectric layer 220 may include a different material from the at least one dielectric layer 120. The at least one dielectric layer 220 may include prepreg and/or polyimide. In some implementations, the metallization portion 202 may be a metallization portion of the package substrate 102. Thus, in some implementations, the metallization portion 202 may be considered part of the package substrate 102. The metallization portion 202 may be a redistribution portion.

The opto-electronic integrated device 101 is located at least partially in the package substrate 102. For example, the opto-electronic integrated device 101 is located in a cavity of the package substrate 102. The opto-electronic integrated device 101 may be coupled to and/or embedded in the package substrate 102 through an adhesive 315. The opto-electronic integrated device 101 may include a layer 110. The layer 110 may include indium tin oxide (ITO) that is located on a surface of the opto-electronic integrated device 101. A lens array 112 is coupled to the opto-electronic integrated device 101. The lens array 112 may be a micro lens array (MLA). The lens array 112 may be coupled to the layer 110 of the opto-electronic integrated device 101. In some implementations, the lens array 112 may be coupled to the layer 110 of the opto-electronic integrated device 101 through a refractive index matching layer. Thus, in some implementations, one or more refractive index matching layer may be located between the lens array 112 and the layer 110. In some implementations, the refractive index matching layer may be part of the lens array 112.

An optical connector 310 is mechanically coupled to the metallization portion 202 and/or the package substrate 102. The optical connector 310 may include one or more casing. An optical fiber 312 is coupled to the optical connector 310. An adhesive may be used to couple the optical connector 310 to the metallization portion 202 and/or the package substrate 102. In some implementations, the optical connector 310 may be coupled to a receiving connector (not show) that is coupled to the metallization portion 202 and/or the package substrate 102. In some implementations, a latch may be used to couple the optical connector 310 to the metallization portion 202 and/or the package substrate 102. An optical beam 109 may travel through the optical fiber, the optical connector 310, the lens array 112 and the layer 110 of the opto-electronic integrated device 101. The optical beam 109 may be a collimated beam.

The package 301 is coupled to the metallization portion 202 and/or the package substrate 102 through a plurality of solder interconnects 214. An underfill 318 may located between the package 301 and the metallization portion 202 and/or the package substrate 102. In some implementations, the underfill 318 may include a composite material comprising an epoxy polymer with filler. The underfill 318 may be coupled to the package 301 and the metallization portion 202.

The package 301 includes an integrated device 303, an integrated device 305, an integrated device 302, an integrated device 304, an integrated device 306, an integrated device 308, an encapsulation layer 392, an encapsulation layer 394, a plurality of through mold interconnects 309, a plurality of through mold interconnects 393 and a plurality of through mold interconnects 395. The package 301 may be an example of a group of integrated device and/or a group of integrated devices.

The encapsulation layer 392 may at least partially encapsulate the integrated device 303, the integrated device 305 and/or the plurality of through mold interconnects 309. The encapsulation layer 394 may at least partially encapsulate the integrated device 302, the integrated device 304, the integrated device 306, the integrated device 308, the plurality of through mold interconnects 309, the plurality of through mold interconnects 393 and/or the plurality of through mold interconnects 395. The encapsulation layer 392 and/or the encapsulation layer 394 may include a mold, a resin, an epoxy and/or a filler. A compression molding process, a transfer molding process, or a liquid molding process may be used to form the encapsulation layer 392 and/or the encapsulation layer 394. The encapsulation layer 392 may be the same or different from the encapsulation layer 394. The encapsulation layer 392 may include a same material and/or a same composition as the encapsulation layer 394. The encapsulation layer 392 may include a different material and/or a different composition as the encapsulation layer 394. The encapsulation layer 392 may be a first encapsulation layer, and the encapsulation layer 394 may be a second encapsulation layer. In some implementations, the encapsulation layer 392 and the encapsulation layer 394 may be considered as one continuous and/or one contiguous encapsulation layer. There may or may not be a boundary interface between the encapsulation layer 392 and the encapsulation layer 394.

The integrated device 303 includes a plurality of through substrate vias 330 and a plurality of interconnects 331. The integrated device 303 includes a front side and a back side. The front side of the integrated device 303 may be the side that includes the plurality of interconnects 331. The back side of the integrated device 303 may include back side interconnects. The integrated device 305 includes a plurality of through substrate vias 350 and a plurality of interconnects 351. The integrated device 305 includes a front side and a back side. The front side of the integrated device 305 may be the side that includes the plurality of interconnects 351. The back side of the integrated device 305 may include back side interconnects. The integrated device 302 includes a plurality of through substrate vias 320 and a plurality of interconnects 321. The integrated device 302 includes a front side and a back side. The front side of the integrated device 302 may be the side that includes the plurality of interconnects 321. The back side of the integrated device 302 may include back side interconnects. The integrated device 304 includes a plurality of through substrate vias 340 and a plurality of interconnects 341. The integrated device 304 includes a front side and a back side. The front side of the integrated device 304 may be the side that includes the plurality of interconnects 341. The back side of the integrated device 304 may include back side interconnects. The integrated device 306 includes a plurality of through substrate vias 360 and a plurality of interconnects 361. The integrated device 306 includes a front side and a back side. The front side of the integrated device 306 may be the side that includes the plurality of interconnects 361. The back side of the integrated device 306 may include back side interconnects. The integrated device 308 includes a plurality of through substrate vias 380 and a plurality of interconnects 381. The integrated device 308 includes a front side and a back side. The front side of the integrated device 308 may be the side that includes the plurality of interconnects 381. The back side of the integrated device 308 may include back side interconnects.

The front side of the integrated device 303 is coupled to the front side of the integrated device 302 and the front side of the integrated device 304. The front side of the integrated device 305 is coupled to the front side of the integrated device 306 and the front side of the integrated device 308. The back side of the integrated device 303 may face in a direction towards the metallization portion 202 and/or the package substrate 102. The back side of the integrated device 305 faces in a direction towards the metallization portion 202 and/or the package substrate 102. The integrated device 305 is located laterally to the integrated device 303. The integrated device 302 is located laterally to the integrated device 304, the integrated device 306 and/or the integrated device 308. The integrated device 303 may be configured to be electrically coupled to the integrated device 302 and/or the integrated device 304. The integrated device 305 may be configured to be electrically coupled to the integrated device 306 and/or the integrated device 308.

The plurality of through mold interconnects 309 may extend through the encapsulation layer 392 and the encapsulation layer 394. The plurality of through mold interconnects 393 may extend through at least part of the encapsulation layer 394. The plurality of through mold interconnects 393 may be configured to be coupled to the integrated device 303. For example, the plurality of through mold interconnects 393 may be configured to be coupled to the integrated device 303 through a plurality of interconnects 397. The plurality of through mold interconnects 395 may extend through at least part of the encapsulation layer 394. The plurality of through mold interconnects 395 may be configured to be coupled to the integrated device 305. For example, the plurality of through mold interconnects 395 may be configured to be coupled to the integrated device 305 through a plurality of interconnects 399.

The substrate antenna 307 is coupled to the package 301 through a plurality of solder interconnects 374. The substrate antenna 307 includes at least one dielectric layer 370 and a plurality of interconnects 372. One or more interconnects from the plurality of interconnects 372 may be configured as one or more antennas. The substrate antenna 307 may be configured to be coupled to (i) the plurality of through mold interconnects 309, (ii) the plurality of through mold interconnects 393, (iii), the plurality of through mold interconnects 395, (iv) the integrated device 302, (v) the integrated device 304, (vi) the integrated device 306 and/or (vii) the integrated device 308, through the plurality of solder interconnects 374.

In some implementations, an electrical path between the substrate antenna 307 and the metallization portion 202, may include (i) at least one solder interconnect from the plurality of solder interconnects 374, (ii) the package 301, and/or (iii) at least one solder interconnect from the plurality of solder interconnects 214. For example, in some implementations, an electrical path between the substrate antenna 307 and the metallization portion 202, may include (i) at least one solder interconnect from the plurality of solder interconnects 374, (ii) at least one through mold interconnect from the plurality of through mold interconnects 309 of the package 301, and/or (iii) at least one solder interconnect from the plurality of solder interconnects 214.

The substrate antenna 307 may be configured to be electrically coupled to the integrated device 303. For example, in some implementations, an electrical path between the substrate antenna 307 and the integrated device 303, may include (i) at least one solder interconnect from the plurality of solder interconnects 374, (ii) at least one though mold interconnect from the plurality of through mold interconnects 393 and/or (iii) at least one interconnect from the plurality of interconnects 397.

The substrate antenna 307 may be configured to be electrically coupled to the integrated device 303 through the integrated device 302. For example, in some implementations, an electrical path between the substrate antenna 307 and the integrated device 303, may include (i) at least one solder interconnect from the plurality of solder interconnects 374, (ii) at least one through substrate via from the plurality of through substrate vias 320, and/or (iii) at least one interconnect from the plurality of interconnects 321.

The substrate antenna 307 may be configured to be electrically coupled to the integrated device 303 through the integrated device 304. For example, in some implementations, an electrical path between the substrate antenna 307 and the integrated device 303, may include (i) at least one solder interconnect from the plurality of solder interconnects 374, (ii) at least one through substrate via from the plurality of through substrate vias 340, and/or (iii) at least one interconnect from the plurality of interconnects 341.

The substrate antenna 307 may be configured to be electrically coupled to the integrated device 305. For example, in some implementations, an electrical path between the substrate antenna 307 and the integrated device 303, may include (i) at least one solder interconnect from the plurality of solder interconnects 374, (ii) at least one though mold interconnect from the plurality of through mold interconnects 395 and/or (iii) at least one interconnect from the plurality of interconnects 399.

The substrate antenna 307 may be configured to be electrically coupled to the integrated device 305 through the integrated device 306. For example, in some implementations, an electrical path between the substrate antenna 307 and the integrated device 305, may include (i) at least one solder interconnect from the plurality of solder interconnects 374, (ii) at least one through substrate via from the plurality of through substrate vias 360, and/or (iii) at least one interconnect from the plurality of interconnects 361.

The substrate antenna 307 may be configured to be electrically coupled to the integrated device 305 through the integrated device 308. For example, in some implementations, an electrical path between the substrate antenna 307 and the integrated device 305, may include (i) at least one solder interconnect from the plurality of solder interconnects 374, (ii) at least one through substrate via from the plurality of through substrate vias 380, and/or (iii) at least one interconnect from the plurality of interconnects 381.

The integrated device 303 may be configured to be electrically coupled to the opto-electronic integrated device 101. In some implementations, an electrical path between the integrated device 303 and the opto-electronic integrated device 101 may include (i) at least one solder interconnect from the plurality of solder interconnects 214 and (ii) at least one metallization interconnect from the plurality of metallization interconnects 222.

The integrated device 305 may be configured to be electrically coupled to the opto-electronic integrated device 101. In some implementations, an electrical path between the integrated device 303 and the opto-electronic integrated device 101 may include (i) at least one solder interconnect from the plurality of solder interconnects 214 and (ii) at least one metallization interconnect from the plurality of metallization interconnects 222.

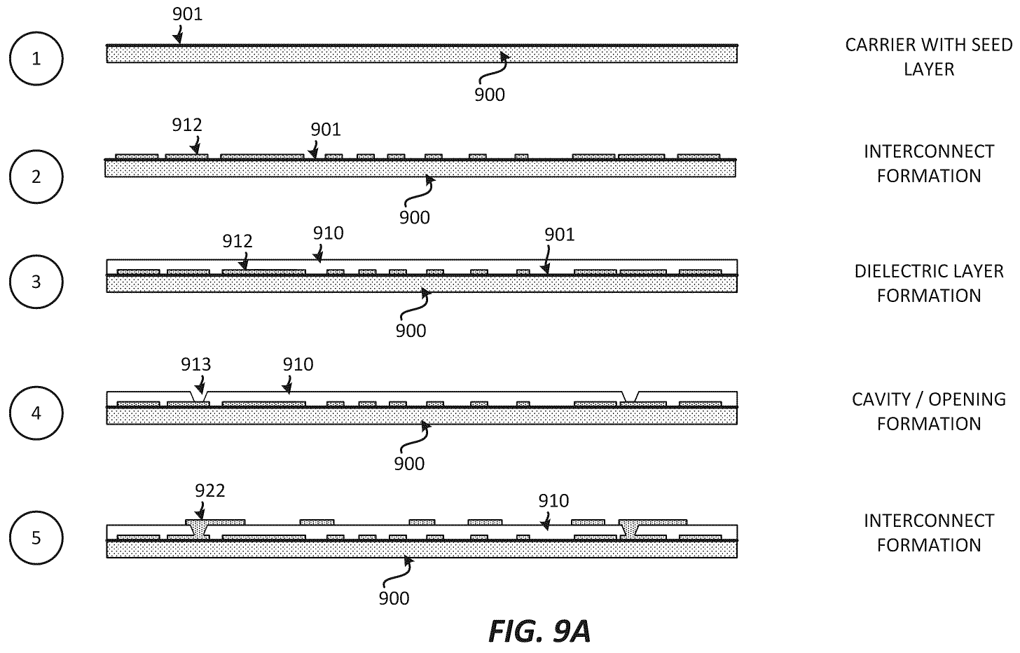

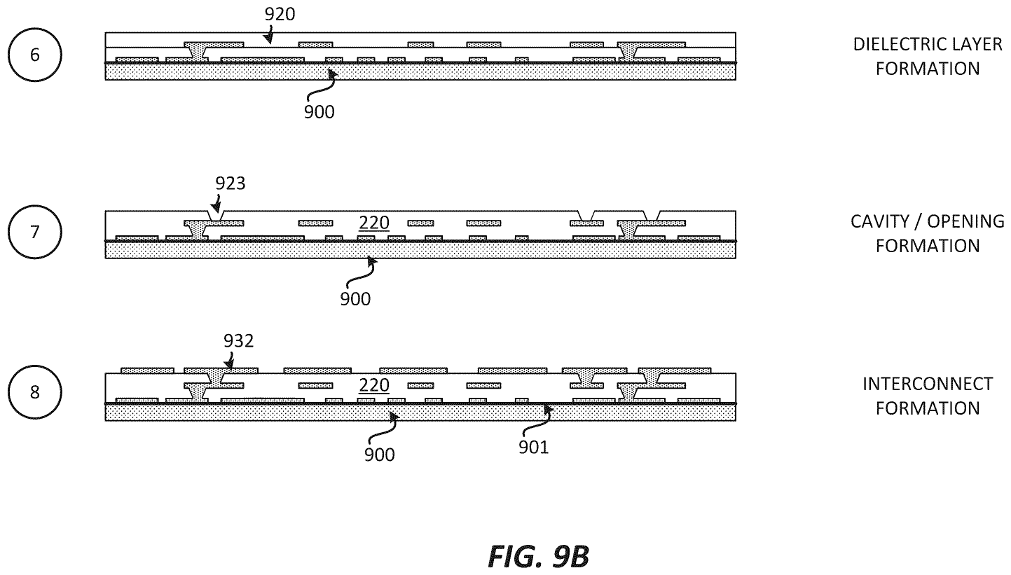

In some implementations, the package 301 may include a metallization portion (not shown). The metallization portion may be coupled to the encapsulation layer 394, the integrated device 302, the integrated device 304, the integrated device 306 and/or the integrated device 308. The metallization portion may be coupled to a first surface (e.g., top surface) of the package 301. The metallization portion may include at least one dielectric layer and a plurality of metallization interconnects. The substrate antenna 307 may be coupled to the metallization portion of the package 301. FIGS. 9A-9B illustrate and describe an example of fabricating a metallization portion.

In some implementations, the integrated device 302 may be configured as a low noise amplifier (LNA). In some implementations, the integrated device 304 may be configured as a switch (SW) (e.g., transmit and/or receive switch). In some implementations, the integrated device 306 may be configured as a radio frequency (RF) pass filter. In some implementations, the integrated device 308 may be configured as a power amplifier (PA). In some implementations, the integrated device 303 may be configured as a first transceiver (e.g., first transmitter and/or first receiver). In some implementations, the integrated device 305 may be configured as a second transceiver (e.g., second transmitter and/or second receiver). The integrated device 303 and/or the integrated device 305 may include a silicon Complementary Metal-Oxide-Semiconductor (CMOS).

### Exemplary Integrated Device

FIG. 4 illustrates a cross sectional profile view of an integrated device 400 that includes a die substrate. The integrated device 400 may represent any of the integrated devices described in the disclosure. For example, the integrated device 400 (or a variation) may represent the integrated device 104, the integrated device 103, the integrated device 105, the integrated device 107, the integrated device 303, the integrated device 305, the integrated device 302, the integrated device 304, the integrated device 306 and/or the integrated device 308.

The integrated device 400 includes a die substrate portion 402 and a die interconnection portion 404. The die substrate portion 402 includes a die substrate 420, an active region 422 and a plurality of through substrate vias 421. The active region 422 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 422 of the die substrate 420.

The die substrate 420 may include silicon (Si). The die substrate 420 may comprise a bulk silicon. The bulk silicon may include a monolith silicon. The plurality of through substrate vias 421 may extend through the die substrate 420. Different implementations may have different thicknesses for the die substrate 420. A back side metallization portion comprising a plurality of metallization interconnects 423 may be coupled to the back side of the die substrate 420. The plurality of metallization interconnects may be coupled to the plurality of through substrate vias 421. The plurality of through substrate vias 421 and/or the plurality of metallization interconnects 423 may be optional. Thus, in some implementations, an integrated device may be free of a plurality of through substrate vias and/or the plurality of metallization interconnects 423.

The die interconnection portion 404 includes at least one dielectric layer 440 and a plurality of die interconnects 442. The die interconnection portion 404 is coupled to the die substrate portion 402. The plurality of die interconnects 442 is coupled to the active region 422 of the die substrate portion 402. The plurality of die interconnects 442 may be coupled to the plurality of through substrate vias 421. The die interconnection portion 404 may also include a plurality of pad interconnects 401 and a passivation layer 406. In some implementations, a back end of line (BEOL) process may be used to fabricate the die interconnection portion 404. The integrated device 400 may include a front side and a back side. The front side of the integrated device 400 may be a side that includes the plurality of pad interconnects 401. The plurality of pad interconnects 401 may be coupled to the plurality of die interconnects 442. The back side of the integrated device 400 may be a side that includes the die substrate 420, the plurality of through substrate vias 421, and/or the plurality of metallization interconnects 423. Different implementations may include an integrated devices with through substrate vias with different shapes and/or sizes. In some implementations, a plurality of through substrate via may extend through the die interconnection portion 404 (e.g., through the at least one dielectric layer 440).

In some implementations, an electrical path to and/or from an active region 422 may include at least one die interconnect from the plurality of die interconnects 442, at least one through substrate via from the plurality of through substrate vias 421. In some implementations, an electrical path to and/or from an active region 422 may include at least one die interconnect from the plurality of die interconnects 442, at least one pad interconnect from the plurality of pad interconnects 401.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G). The packages (e.g., 100, 300, 400) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

Having described various packages, a sequence for fabricating a package will now be described below.

### Exemplary Sequence For Fabricating a Package Comprising an Opto-Electronic Integrated Device and Stacked Integrated Devices

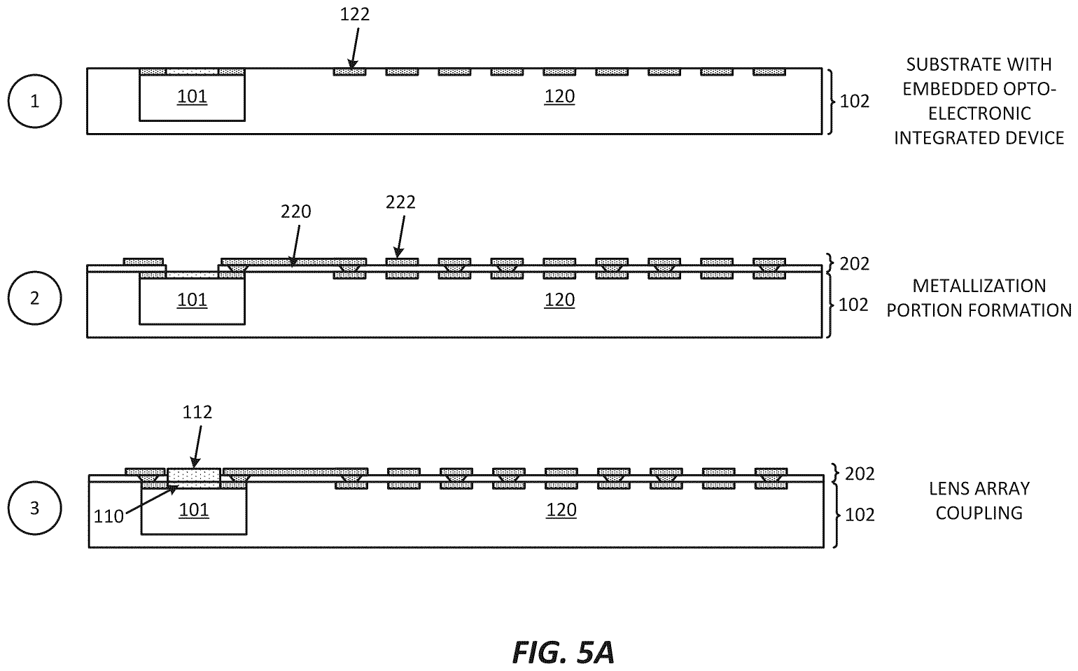

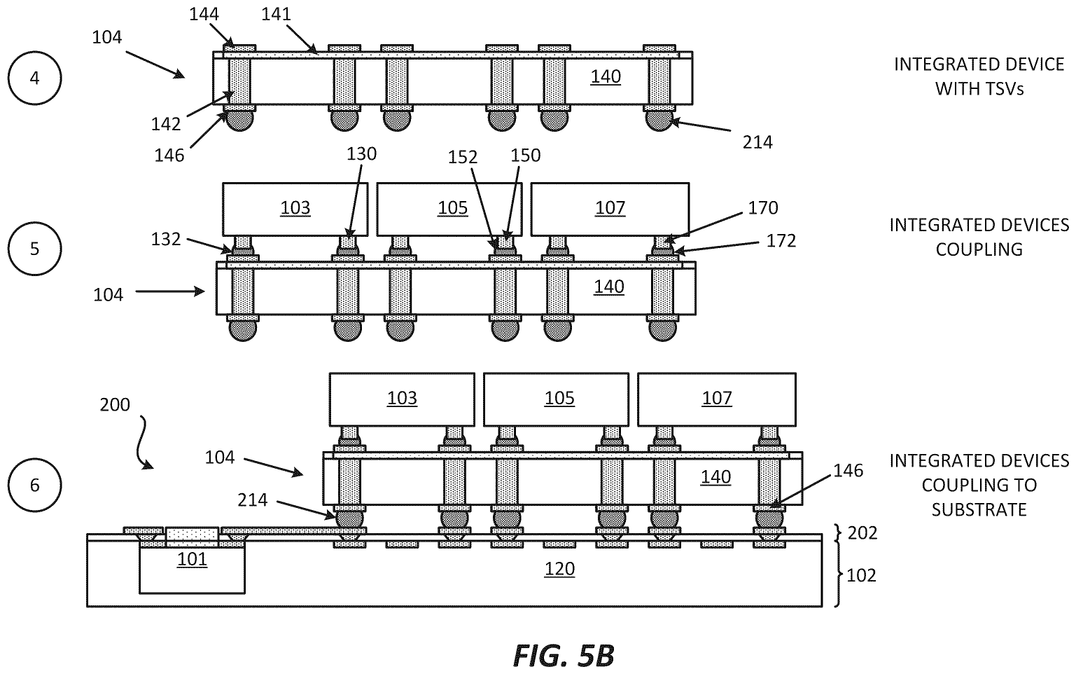

In some implementations, fabricating a package includes several processes. FIGS. 5A-5B illustrate an exemplary sequence for providing or fabricating a package. In some implementations, the sequence of FIGS. 5A-5B may be used to provide or fabricate the package 200 of FIG. 2. However, the process of FIGS. 5A-5B may be used to fabricate any of the packages (e.g., 100) described in the disclosure.

It should be noted that the sequence of FIGS. 5A-5B may combine one or more stages in order to simplify and/or clarify the sequence for providing or fabricating a package. In some implementations, the order of the processes may be changed or modified. In some implementations, one or more of processes may be replaced or substituted without departing from the spirit of the disclosure.

Stage 1 of FIG. 5A, illustrates a state after a package substrate 102 and an opto-electronic integrated device 101 are provided. The package substrate 102 includes at least one dielectric layer 120 and a plurality of interconnects 122. The package substrate 102 may include a cavity. The opto-electronic integrated device 101 may be located and/or embedded in the package substrate 102. For example, the opto-electronic integrated device 101 may be located in a cavity of the package substrate 102. An adhesive may be used to couple and/or embed in the opto-electronic integrated device 101 in package substrate 102. In some implementations, the opto-electronic integrated device 101 may be coupled to a surface of the package substrate 102.

Stage 2 of FIG. 5A, illustrates a state after a metallization portion 202 is formed and coupled to the package substrate 102 and/or the opto-electronic integrated device 101. The metallization portion 202 may include at least one dielectric layer 220 and a plurality of metallization interconnects 222. The plurality of metallization interconnects 222 may be coupled to the plurality of interconnects 122 and/or the opto-electronic integrated device 101. The metallization portion 202 may be a redistribution portion. In some implementations, the metallization portion 202 may be considered part of the package substrate 102. In some implementations, the metallization portion 202 may be fabricated using the process illustrated and described below in FIGS. 9A-9B.

Stage 3 of FIG. 5A, illustrates a state after a lens array 112 that is coupled to the opto-electronic integrated device 101. The lens array 112 may be placed over and/or coupled to a layer 110 of the opto-electronic integrated device 101.

Stage 4 of FIG. 5B, illustrates a state after an integrated device 104 is provided. The integrated device 104 may include a die substrate 140, an active region 141, a plurality of through substrate vias 142, a plurality of interconnects 144 and a plurality of interconnects 146. The plurality of interconnects 146 may be a plurality of back side interconnects. The integrated device 400 of FIG. 4 may be a detailed example of the integrated device 104.

Stage 5 of FIG. 5B, illustrates a state after an integrated device 103, an integrated device 105 and an integrated device 107 are coupled to the integrated device 104. The integrated device 103 may be coupled to the integrated device 104 through a plurality of pillar interconnects 130 and a plurality of solder interconnects 132. The integrated device 105 may be coupled to the integrated device 104 through a plurality of pillar interconnects 150 and a plurality of solder interconnects 152. The integrated device 107 may be coupled to the integrated device 104 through a plurality of pillar interconnects 170 and a plurality of solder interconnects 172. A solder reflow process may be used to couple the integrated device 103, the integrated device 105 and the integrated device 107 to the integrated device 104. Stage 5 may illustrate a stack of integrated devices (e.g., vertical stack of integrated devices, vertically stacked integrated devices) and/or a group of integrated devices.

Stage 6 of FIG. 5B, illustrates a state after the stack of integrated devices is coupled to the metallization portion 202 and/or the package substrate 102. The integrated device 104 may be coupled to the metallization portion 202 through a plurality of solder interconnects 214. A solder reflow process may be used to couple the integrated device 104 to the plurality of metallization interconnects 222 of the metallization portion 202 through the plurality of solder interconnects 214. Stage 6 may illustrate an example of the package 200 that includes the package substrate 102, the metallization portion 202, the opto-electronic integrated device 101, the integrated device 104, the integrated device 103, the integrated device 105 and the integrated device 107.

### Exemplary Sequence For Fabricating a Package Comprising Integrated Devices

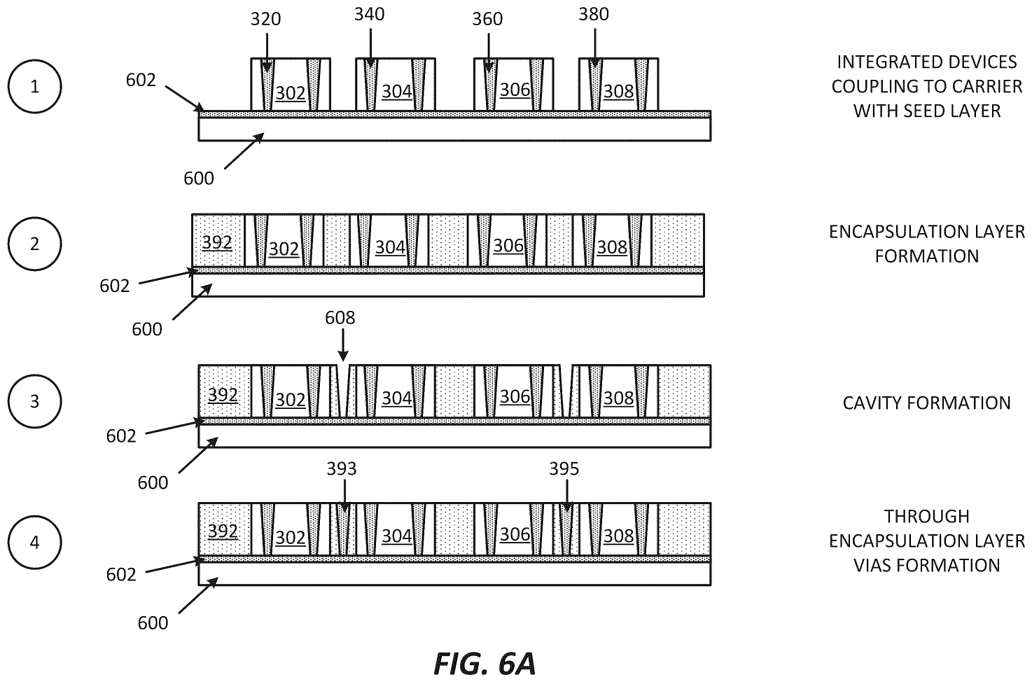

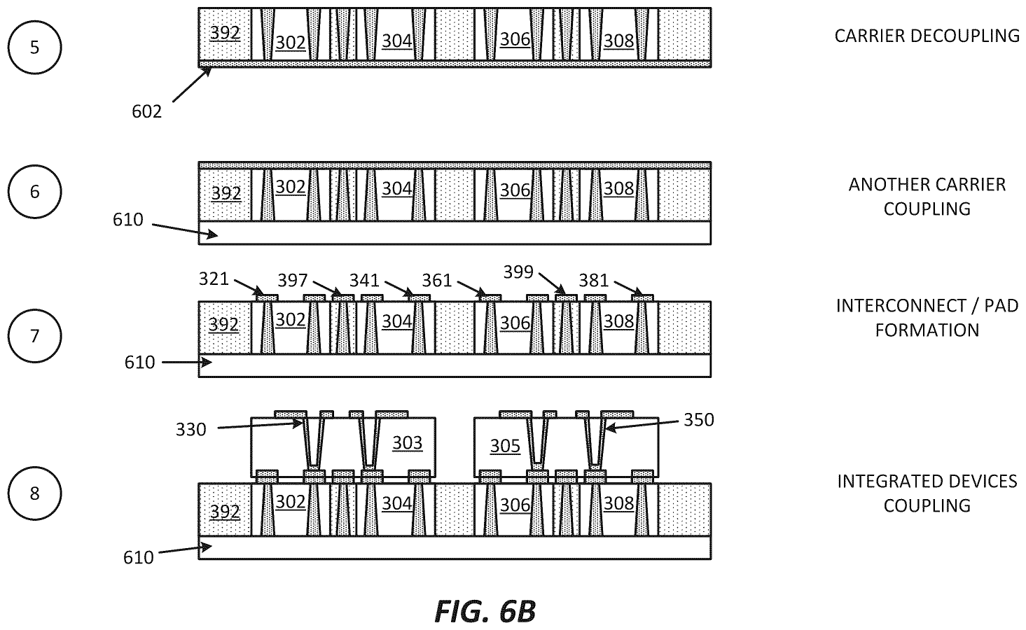

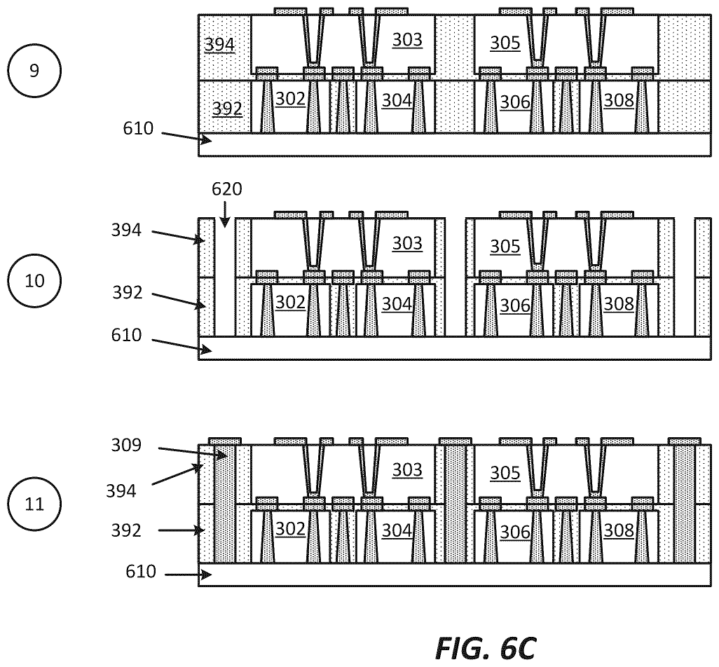

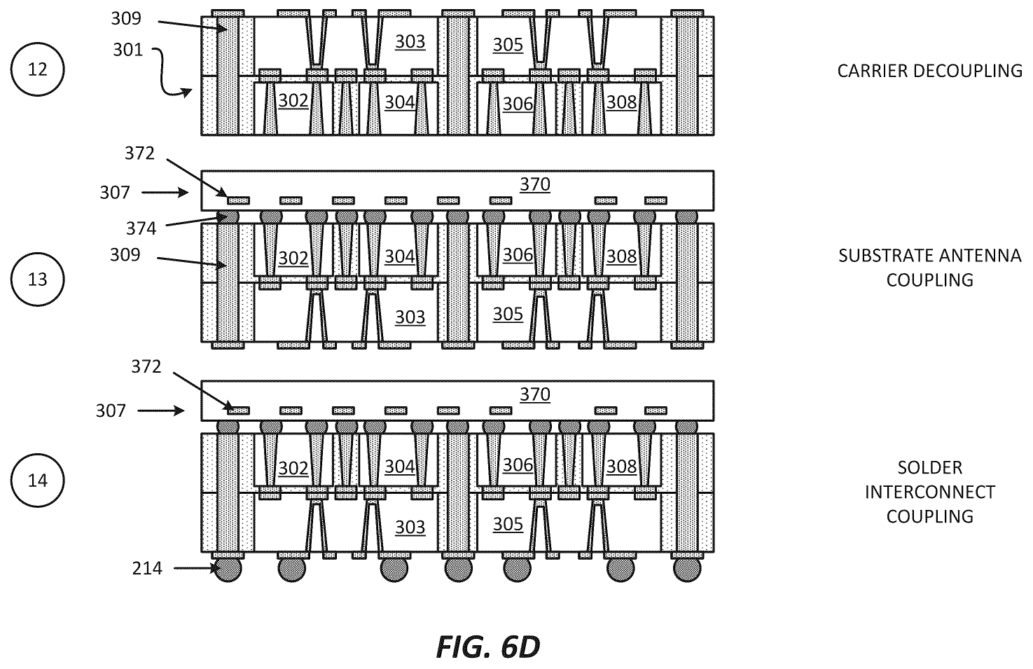

In some implementations, fabricating a package includes several processes. FIGS. 6A-6D illustrate an exemplary sequence for providing or fabricating a package comprising integrated devices and/or a group of integrated devices. In some implementations, the sequence of FIGS. 6A-6D may be used to provide or fabricate the package 301 of FIG. 3. However, the process of FIGS. 6A-6D may be used to fabricate any of the packages described in the disclosure.

It should be noted that the sequence of FIGS. 6A-6D may combine one or more stages in order to simplify and/or clarify the sequence for providing or fabricating a package. In some implementations, the order of the processes may be changed or modified. In some implementations, one or more of processes may be replaced or substituted without departing from the spirit of the disclosure.

Stage 1 of FIG. 6A, illustrates a state after a carrier 600 and a seed layer 602 are provided, and a plurality of integrated devices are placed and/or coupled to the seed layer 602 and the carrier 600. The carrier 600 may be a glass carrier. The integrated device 302, the integrated device 304, the integrated device 306 and/or the integrated device 308 is/are placed and coupled to the seed layer 602 and/or the carrier 600. In some implementations, the front sides of the integrated device 302, the integrated device 304, the integrated device 306 and/or the integrated device 308 is/are placed and coupled to the seed layer 602 and/or the carrier 600.

Stage 2 of FIG. 6A, illustrates a state after an encapsulation layer 392 is formed and coupled to the seed layer 602. The encapsulation layer 392 may at least partially encapsulate the integrated device 302, the integrated device 304, the integrated device 306 and/or the integrated device 308. The encapsulation layer 392 may include a mold, a resin, an epoxy and/or a filler. A compression molding process, a transfer molding process, or a liquid molding process may be used to form the encapsulation layer 392. The encapsulation layer 392 may be over molded and portions of the encapsulation layer 392 may be removed.

Stage 3 of FIG. 6A, illustrates a state after a plurality of cavities 608 are formed in the encapsulation layer 392. A laser process (e.g., laser ablation process) may be used to form the plurality of cavities 608. The plurality of cavities 608 may expose part of the seed layer 602.

Stage 4 of FIG. 6A, illustrates a state after a plurality of through mold interconnects 393 and a plurality of through mold interconnects 395 are formed. A plating process may be used to form the plurality of through mold interconnects 393 and the plurality of through mold interconnects 395 in the encapsulation layer 392.

Stage 5 of FIG. 6B, illustrates a state after the carrier 600 is de-bonded, leaving the seed layer 602 coupled to the encapsulation layer 392, the integrated device 302, the integrated device 304, the integrated device 306 and/or the integrated device 308. The carrier 600 may be detached from the seed layer 602.

Stage 6 of FIG. 6B, illustrates a state after the encapsulation layer 392 and the back side of the integrated device 302, the back side of the integrated device 304, the back side of the integrated device 306 and the back side of the integrated device 308 are placed and coupled to a carrier 610. The carrier 610 may be a glass carrier.

Stage 7 of FIG. 6B, illustrates a state after a plurality of interconnects are formed. The plurality of interconnects may be formed over the seed layer 602. A plating process and/or a patterning process may be used to form the plurality of interconnects. Part of the seed layer 602 may be removed. The plurality of interconnects that are formed may include a plurality of interconnects 321, a plurality of interconnects 341, a plurality of interconnects 361, a plurality of interconnects 381, a plurality of interconnects 397 and/or a plurality of interconnects 399.

Stage 8 of FIG. 6B, illustrates a state after an integrated device 303 is coupled to the integrated device 302 and the integrated device 304, and after an integrated device 305 is coupled to the integrated device 306 and the integrated device 308. In some implementations, a hybrid bonding process (e.g., copper to copper bonding process) may be used to couple the front side of the integrated device 303 to (i) the front side of the integrated device 302 and (ii) the front side of the integrated device 304. Interconnects of the integrated device 303 may be coupled to interconnects of the integrated device 302 and interconnects of the integrated device 304. In some implementations, a hybrid bonding process (e.g., copper to copper bonding process) may be used to couple the front side of the integrated device 305 to (i) the front side of the integrated device 306 and (ii) the front side of the integrated device 308. Interconnects of the integrated device 305 may be coupled to interconnects of the integrated device 306 and interconnects of the integrated device 308.

Stage 9 of FIG. 6C, illustrates a state after an encapsulation layer 394 is formed and coupled to the encapsulation layer 392, the integrated device 303 and/or the integrated device 305. The encapsulation layer 394 may at least partially encapsulate the integrated device 303 and/or the integrated device 304. The encapsulation layer 394 may include a mold, a resin, an epoxy and/or a filler. A compression molding process, a transfer molding process, or a liquid molding process may be used to form the encapsulation layer 394. The encapsulation layer 394 may be the same, similar or different from the encapsulation layer 392. There may or may not be a boundary interface between the encapsulation layer 392 and the encapsulation layer 394. In some implementations, a surface of the encapsulation layer 394 may be planar with a surface of the interconnects of the integrated device 303 and/or a surface of the interconnects of the integrated device 305.

Stage 10 of FIG. 6C, illustrates a state after a plurality of cavities 620 are formed in the encapsulation layer 394 and the encapsulation layer 392. A laser process (e.g., laser ablation process) may be used to form the plurality of cavities 620.

Stage 11 of FIG. 6C, illustrates a state after a plurality of through mold interconnects 309 (e.g., through mold vias (TMVs)) are formed. A plating process may be used to form the plurality of through mold interconnects 309 in the encapsulation layer 394 and the encapsulation layer 392. The plurality of through mold interconnects 309 may be formed in the plurality of cavities 620. In some implementations, a plurality of interconnects may be formed on a surface of the encapsulation layer 394.

Stage 12 of FIG. 6D, illustrates a state after the carrier 610 is decoupled from the encapsulation layer 392. The carrier 610 may be detached from the encapsulation layer 392. Stage 12 may illustrate a package 301.

Stage 13 of FIG. 6D, illustrates a state after a substrate antenna 307 is coupled to the package 301 through a plurality of solder interconnects 374. A solder reflow process may be used to couple the substrate antenna 307 to the package 301. Once the substrate antenna 307 is coupled to the package 301, the substrate antenna 307 may considered part of the package 301. The substrate antenna 307 may include at least one dielectric layer 370 and a plurality of interconnects 372. At least one interconnect from the plurality of interconnects 372 may be configured as at least one antenna.

Stage 14 of FIG. 6D, illustrates a state after a plurality of solder interconnects 214 are coupled to the package 301. A solder reflow process may be used to couple the plurality of solder interconnects to the package 301.

### Exemplary Sequence For Fabricating a Package Comprising an Opto-Electronic Integrated Device and Stacked Integrated Devices

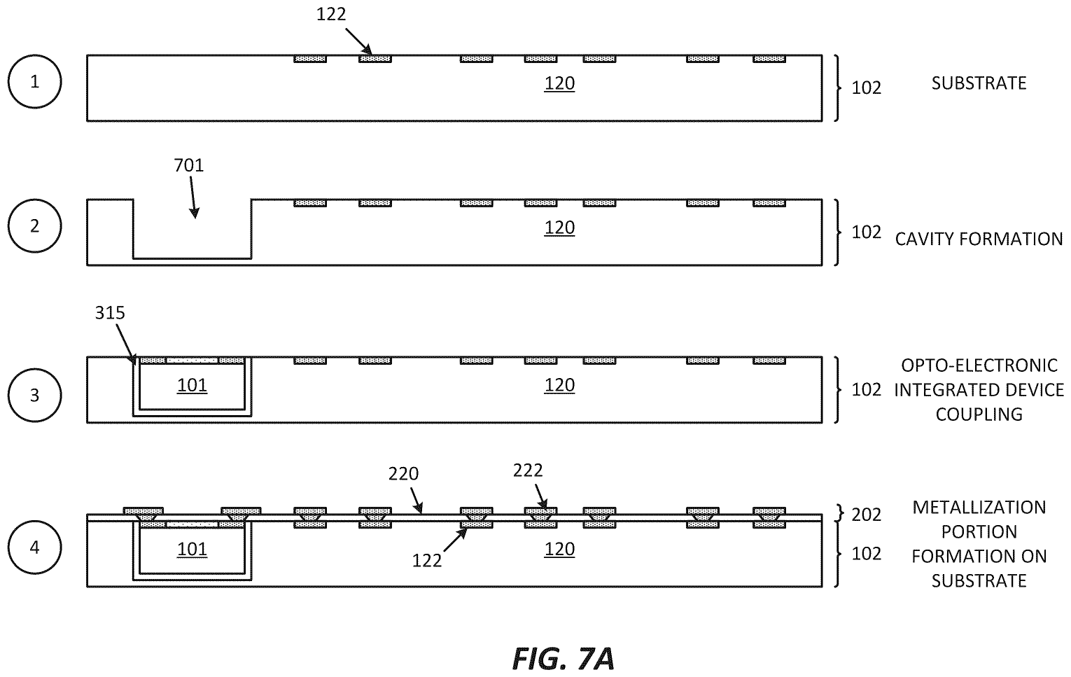

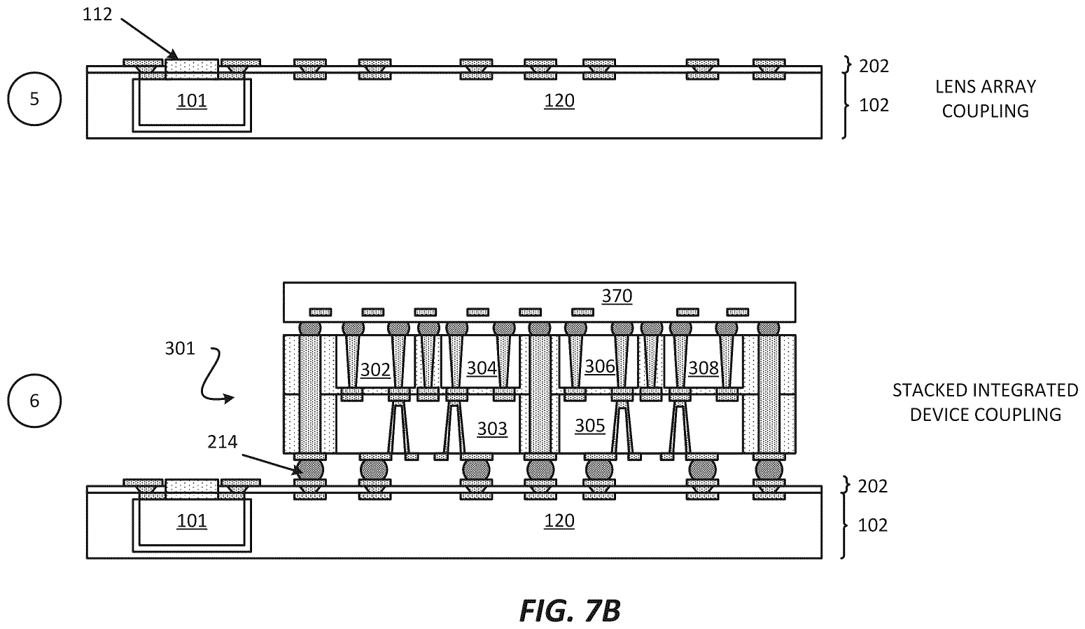

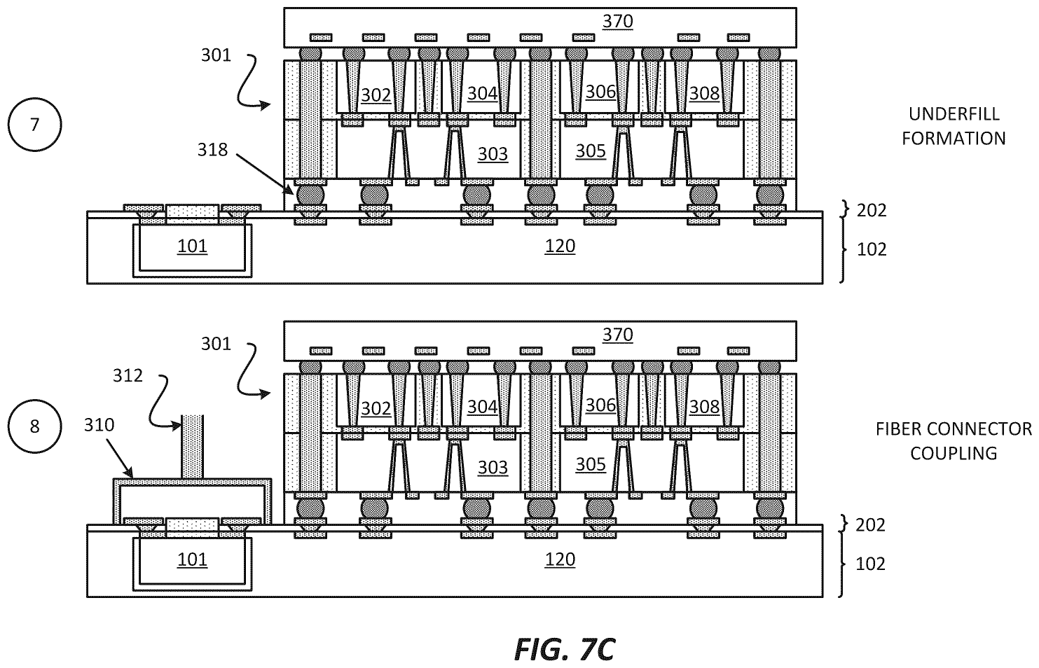

In some implementations, fabricating a package includes several processes. FIGS. 7A-7C illustrate an exemplary sequence for providing or fabricating a package. In some implementations, the sequence of FIGS. 7A-7C may be used to provide or fabricate the package 300 of FIG. 3. However, the process of FIGS. 7A-7C may be used to fabricate any of the packages described in the disclosure.

It should be noted that the sequence of FIGS. 7A-7C may combine one or more stages in order to simplify and/or clarify the sequence for providing or fabricating a package. In some implementations, the order of the processes may be changed or modified. In some implementations, one or more of processes may be replaced or substituted without departing from the spirit of the disclosure.

Stage 1 of FIG. 7A, illustrates a state after a package substrate 102 is provided. The package substrate 102 includes at least one dielectric layer 120 and a plurality of interconnects 122. The package substrate 102 may be a laminated substrate.

Stage 2 of FIG. 7A, illustrates a state after a cavity 701 is formed in the package substrate 102. The cavity 701 may be formed using a laser process (e.g., laser ablation process).

Stage 3 of FIG. 7A, illustrates a state after an opto-electronic integrated device 101 is placed in the cavity 701 of the package substrate 102. The opto-electronic integrated device 101 may be coupled to the package substrate 102 through an adhesive 315. The adhesive 315 may be located between the opto-electronic integrated device 101 (e.g., back side and/or side surface(s) of the opto-electronic integrated device) and the at least one dielectric layer 120 of the package substrate 102.

Stage 4 of FIG. 7A, illustrates a state after a metallization portion 202 is formed and coupled to the package substrate 102 and the opto-electronic integrated device 101. The metallization portion 202 may include at least one dielectric layer 220 and a plurality of metallization interconnects 222. The plurality of metallization interconnects 222 may be coupled to the opto-electronic integrated device 101 and/or the plurality of interconnects 122. A deposition, a lamination, an exposure, a development and/or an etching process may be used to form and pattern the at least one dielectric layer. A plating process and/or a patterning process may be used to form the metallization interconnects. In some implementations, the metallization portion 202 may be considered part of the package substrate 102. Thus, the at least one dielectric layer 220 and the plurality of metallization interconnects 222 may be considered part of the package substrate 102. In some implementations, the metallization portion 202 may be fabricated using the process described in FIGS. 9A-9B.

Stage 5 of FIG. 7B, illustrates a state after a lens array 112 is coupled to the opto-electronic integrated device 101.

Stage 6 of FIG. 7B, illustrates a state after the package 301 is coupled to the metallization portion 202 and/or the package substrate 102 through a plurality of solder interconnects 214. A solder reflow process may be used to couple the package 301 to the metallization portion 202 and/or the package substrate 102. An example of providing and/or fabricating the package 301 is illustrated and described in FIGS. 6A-6D.

Stage 7 of FIG. 7C, illustrates a state after an underfill 318 is formed between the package 301 and the metallization portion 202. The underfill 318 is coupled to the metallization portion 202 and the package 301. In some implementations, the underfill 318 may include a composite material comprising an epoxy polymer with filler. The underfill 318 may include different materials and/or a different composition from the encapsulation layer (e.g., 394) of the package 301.

Stage 8 of FIG. 7C, illustrates a state after an optical connector 310 is mechanically coupled to the metallization portion 202 and/or the package substrate 102. The optical connector 310 may include one or more casing. An optical fiber 312 is coupled to the optical connector 310. An adhesive may be used to couple the optical connector 310 to the metallization portion 202 and/or the package substrate 102. In some implementations, the optical connector 310 may be coupled to a receiving connector (not show) that is coupled to the metallization portion 202 and/or the package substrate 102. In some implementations, a latch may be used to couple the optical connector 310 to the metallization portion 202 and/or the package substrate 102.

### Exemplary Flow Diagram of a Method for Fabricating a Package Comprising an Opto-Electronic Integrated Device and Stacked Integrated Devices

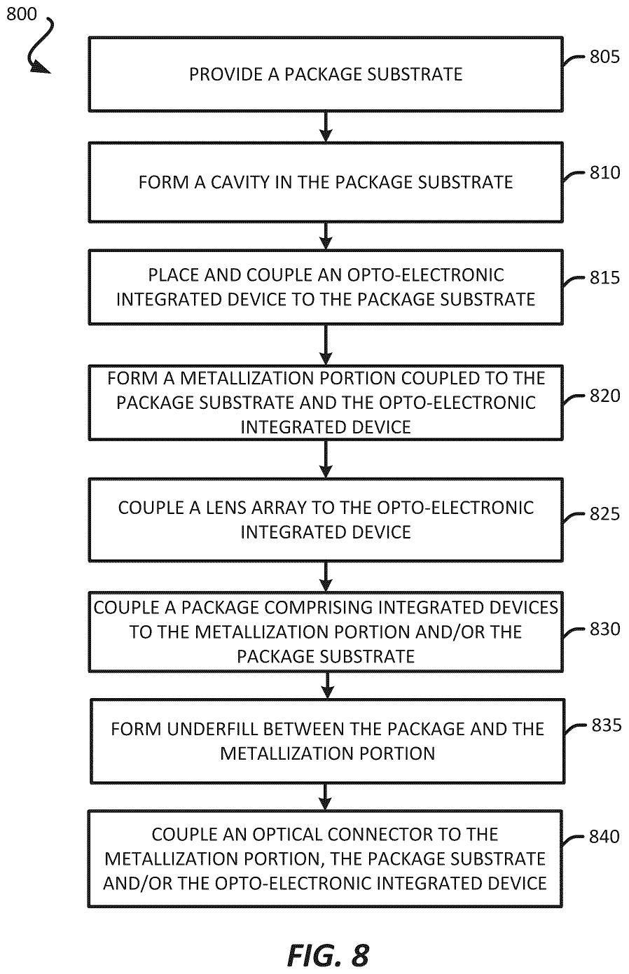

In some implementations, fabricating a package includes several processes. FIG. 8 illustrates an exemplary flow diagram of a method 800 for providing or fabricating a package. In some implementations, the method 800 of FIG. 8 may be used to provide or fabricate the packages of at least FIGS. 1-3. The method 800 will be used to describe the fabrication of the package 300 of FIG. 3.

It should be noted that the method 800 of FIG. 8 may combine one or more processes in order to simplify and/or clarify the method for providing or fabricating a package. In some implementations, the order of the processes may be changed or modified.

The method provides (at 805) a package substrate. Stage 1 of FIG. 7A, illustrates and describes an example of a state after a package substrate 102 is provided. The package substrate 102 includes at least one dielectric layer 120 and a plurality of interconnects 122. The package substrate 102 may be a laminated substrate.

The method forms (at 810) a cavity in the package substrate. Stage 2 of FIG. 7A, illustrates and describes an example of a state after a cavity 701 is formed in the package substrate 102. The cavity 701 may be formed using a laser process (e.g., laser ablation process).

The method couple (at 815) an opto-electronic integrated device to the package substrate. Stage 3 of FIG. 7A, illustrates and describes an example of a state after an opto-electronic integrated device 101 is placed in the cavity 701 of the package substrate 102. The opto-electronic integrated device 101 may be coupled to the package substrate 102 through an adhesive 315. The adhesive 315 may be located between the opto-electronic integrated device 101 (e.g., back side and/or side surface(s) of the opto-electronic integrated device) and the at least one dielectric layer 120 of the package substrate 102.

The method forms (at 820) a metallization portion that is coupled to the package substrate and the opto-electronic integrated device. Stage 4 of FIG. 7A, illustrates and describes an example of a state after a metallization portion 202 is formed and coupled to the package substrate 102 and the opto-electronic integrated device 101. The metallization portion 202 may include at least one dielectric layer 220 and a plurality of metallization interconnects 222. The plurality of metallization interconnects 222 may be coupled to the opto-electronic integrated device 101 and/or the plurality of interconnects 122. A deposition, a lamination, an exposure, a development and/or an etching process may be used to form and pattern the at least one dielectric layer. A plating process and/or a patterning process may be used to form the metallization interconnects. In some implementations, the metallization portion 202 may be considered part of the package substrate 102. Thus, the at least one dielectric layer 220 and the plurality of metallization interconnects 222 may be considered part of the package substrate 102. In some implementations, the metallization portion 202 may be fabricated using the process described in FIGS. 9A-9B.

The method couples (at 825) a lens array to the opto-electronic integrated device. Stage 5 of FIG. 7B, illustrates and describes an example of a state after a lens array 112 is coupled to the opto-electronic integrated device 101.

The method couples (at 830) a package to the metallization portion and/or the package substrate. Stage 6 of FIG. 7B, illustrates and describes an example of a state after the package 301 is coupled to the metallization portion 202 and/or the package substrate 102 through a plurality of solder interconnects 214. A solder reflow process may be used to couple the package 301 to the metallization portion 202 and/or the package substrate 102. An example of providing and/or fabricating the package 301 is illustrated and described in FIGS. 6A-6D.

The method forms (at 835) an underfill between the package and the metallization portion. Stage 7 of FIG. 7C, illustrates and describes an example of a state after an underfill 318 is formed between the package 301 and the metallization portion 202. The underfill 318 is coupled to the metallization portion 202 and the package 301. In some implementations, the underfill 318 may include a composite material comprising an epoxy polymer with filler. The underfill 318 may include different materials and/or a different composition from the encapsulation layer (e.g., 394) of the package 301.

The method couples (at 840) an optical connector to the opto-electronic integrated device, the metallization portion and/or the package substrate. Stage 8 of FIG. 7C, illustrates and describes an example of a state after an optical connector 310 is mechanically coupled to the metallization portion 202 and/or the package substrate 102. The optical connector 310 may include one or more casing. An optical fiber 312 is coupled to the optical connector 310. An adhesive may be used to couple the optical connector 310 to the metallization portion 202 and/or the package substrate 102. In some implementations, the optical connector 310 may be coupled to a receiving connector (not show) that is coupled to the metallization portion 202 and/or the package substrate 102. In some implementations, a latch may be used to couple the optical connector 310 to the metallization portion 202 and/or the package substrate 102.

### Exemplary Sequence for Fabricating a Metallization Portion

In some implementations, fabricating a substrate includes several processes. FIGS. 9A-9B illustrate an exemplary sequence for providing or fabricating a metallization portion. In some implementations, the sequence of FIGS. 9A-9B may be used to provide or fabricate the metallization portion 202. However, the process of FIGS. 9A-9B may be used to fabricate any of the metallization portions described in the disclosure.

It should be noted that the sequence of FIGS. 9A-9B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure. In some implementations, the process of FIGS. 9A-9B may be used to fabricate a package substrate (e.g., 102).

Stage 1, as shown in FIG. 9A, illustrates a state after a carrier 900 is provided. A seed layer 901 may be located over the carrier 900. The carrier 900 may be replaced with other components and/or materials.

Stage 2 illustrates a state after a plurality of interconnects 912 are formed. The interconnects 912 may be located over the seed layer 901. A lithography process, a plating process, a strip process and/or an etching process may be used to form the plurality of interconnects 912. The interconnects 912 may represent at least some of the interconnects from the plurality of metallization interconnects 123.

Stage 3 illustrates a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

Stage 4 illustrates a state after a plurality of cavities 913 is formed in the dielectric layer 910. The plurality of cavities 913 may be formed using an etching process (e.g., photo etching process), a laser process, an exposure process and/or a development process.

Stage 5 illustrates a state after interconnects 922 are formed in and over the dielectric layer 910, including in and over the plurality of cavities 913. For example, a via, pad and/or traces may be formed. A lithography process, a plating process, a strip process and/or an etching process may be used to form the interconnects.

Stage 6, as shown in FIG. 9B, illustrates a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

Stage 7, illustrates a state after a plurality of cavities 923 are formed in the dielectric layer 220. The dielectric layer 220 may represent the dielectric layer 910 and/or the dielectric layer 920. The plurality of cavities 923 may be formed using an etching process (e.g., photo etching process), a laser process, an exposure process and/or a development process.

Stage 8 illustrates a state after interconnects 932 are formed in and over the dielectric layer 220, including in and over the plurality of cavities 923. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

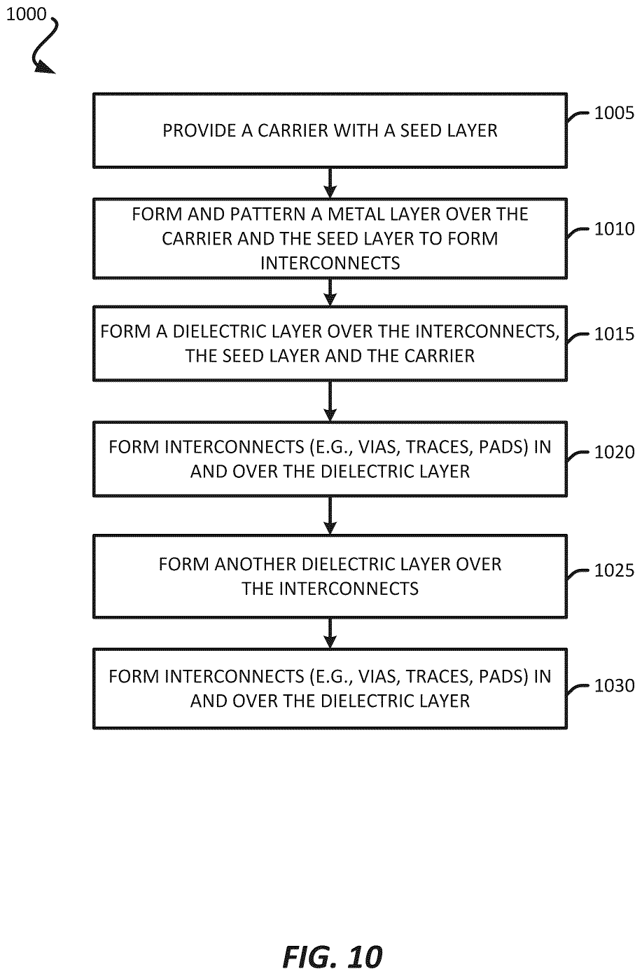

In some implementations, fabricating a substrate includes several processes. FIG. 10 illustrates an exemplary flow diagram of a method 1000 for providing or fabricating a metallization portion. In some implementations, the method 1000 of FIG. 10 may be used to provide or fabricate the metallization portion(s) of the disclosure. For example, the method 1000 of FIG. 10 may be used to fabricate the metallization portion 202.

It should be noted that the method 1000 of FIG. 10 may combine one or more processes in order to simplify and/or clarify the method for providing or fabricating a metallization portion. In some implementations, the order of the processes may be changed or modified. In some implementations, the method 800 of FIG. 10 may be used to fabricate a package substrate (e.g., 102).

The method provides (at 1005) a carrier with a seed layer. Stage 1 of FIG. 9A, illustrates and describes an example of a state after a carrier 900 is provided. A seed layer 901 may be located over the carrier 900. The carrier 900 may be replaced with other components and/or materials.

The method forms and patterns (at 1010) a plurality of interconnects. Stage 2 of FIG. 9A, illustrates and describes an example of a state after a plurality of interconnects 912 are formed. The interconnects 912 may be located over the seed layer 901. A lithography process, a plating process, a strip process and/or an etching process may be used to form the plurality of interconnects 912. The interconnects 912 may represent at least some of the interconnects from the plurality of metallization interconnects 123.

The method forms (at 1010) a dielectric layer. Stage 3 of FIG. 9A, illustrates and describes an example of a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

The method forms (at 1020) a plurality of interconnects. Forming a plurality of interconnects may including forming a plurality of cavities in a dielectric layer and a performing a plating process. Stage 4 of FIG. 9A, illustrates and describes an example of a state after a plurality of cavities 913 is formed in the dielectric layer 910. The plurality of cavities 913 may be formed using an etching process (e.g., photo etching process), a laser process, an exposure process and/or a development process.

Stage 5 of FIG. 9A, illustrates and describes an example of a state after interconnects 922 are formed in and over the dielectric layer 910, including in and over the plurality of cavities 913. For example, a via, pad and/or traces may be formed. A lithography process, a plating process, a strip process and/or an etching process may be used to form the interconnects.

The method forms (at 1025) another dielectric layer. Stage 6 of FIG. 9B, illustrates and describes an example of a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

The method forms (at 1030) a plurality of interconnects. Forming a plurality of interconnects may including forming a plurality of cavities in a dielectric layer and a performing a plating process. Stage 7 of FIG. 9B, illustrates and describes an example of a state after a plurality of cavities 923 is formed in the dielectric layer 220. The dielectric layer 220 may represent the dielectric layer 910 and/or the dielectric layer 920. The plurality of cavities 923 may be formed using an etching process (e.g., photo etching process), a laser process, an exposure process and/or a development process.

Stage 8 of FIG. 9B, illustrates and describes an example of a state after interconnects 932 are formed in and over the dielectric layer 220, including in and over the plurality of cavities 923. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

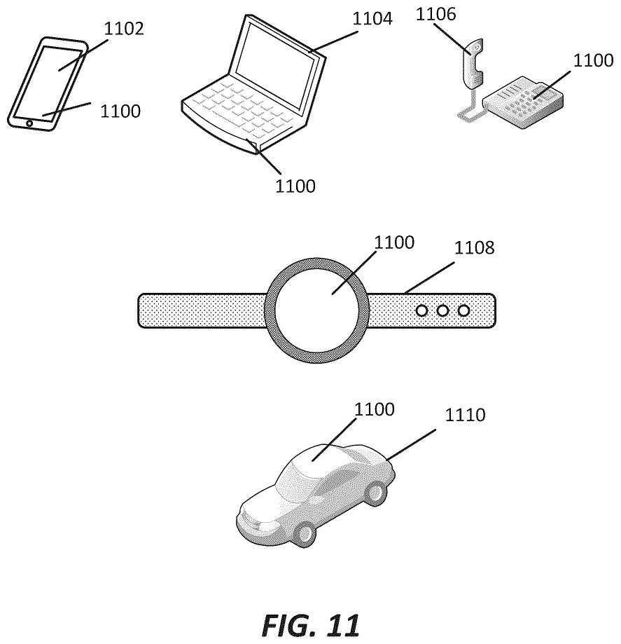

FIG. 11 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5B, 6A-6D, 7A-7C, 8, 9A-9B and/or 10-11 may be rearranged and/or combined into a single component, process, feature or function or embodied in several components, processes, or functions. Additional elements, components, processes, and/or functions may also be added without departing from the disclosure. It should also be noted FIGS. 1-4, 5A-5B, 6A-6D, 7A-7C, 8, 9A-9B and/or 10-11 and its corresponding description in the present disclosure is not limited to dies and/or ICs. In some implementations, FIGS. 1-4, 5A-5B, 6A-6D, 7A-7C, 8, 9A-9B and/or 10-11 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. An interconnect may include one or more metal components (e.g., seed layer+metal layer). In some implementations, an interconnect is an electrically conductive material that may be configured to provide an electrical path for a current (e.g., a data signal, ground or power). An interconnect may be part of a circuit. An interconnect may include more than one element or component. An interconnect may be defined by one or more interconnects. Different implementations may use similar or different processes to form the interconnects. In some implementations, a chemical vapor deposition (CVD) process and/or a physical vapor deposition (PVD) process for forming the interconnects. For example, a sputtering process, a spray coating, and/or an electro plating process or electroless plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A device comprising a substrate; an opto-electronic integrated device coupled to the substrate; a first integrated device coupled to the substrate through a first plurality of solder interconnects; and a second integrated device coupled to the first integrated device through a second plurality of solder interconnects.

Aspect 2: The device of aspect 1, wherein the opto-electronic integrated device is located at least partially in the substrate.

Aspect 3: The device of aspects 1 through 2, wherein the first integrated device comprises a front side and a back side, and wherein the back side of the first integrated device is coupled to the substrate through the first plurality of solder interconnects.

Aspect 4: The device of aspect 3, wherein the second integrated device is coupled to the front side of the first integrated device through the second plurality of solder interconnects.

Aspect 5: The device of aspects 1 through 4, further comprising a third integrated device coupled to the first integrated device through a third plurality of solder interconnects; and a fourth integrated device coupled to the first integrated device through a fourth plurality of solder interconnects.

Aspect 6: The device of aspect 5, wherein the second integrated device comprises a low noise amplifier, wherein the third integrated device comprises a filter, and wherein the fourth integrated device comprises a power amplifier.

Aspect 7: The device of aspects 1 through 6, wherein the second integrated device is configured to be electrically coupled to the opto-electronic integrated device through the first integrated device and the substrate.

Aspect 8: The device of aspects 1 through 7, wherein the opto-electronic integrated device is configured to convert a first optical beam into at least one first electrical signal, and wherein the opto-electronic integrated device is further configured to convert at least one second electrical signal into a second optical beam.

Aspect 9: The device of aspect 1 through 8, further comprises a plurality of lenses coupled to the opto-electronic integrated device.

Aspect 10: The device of aspects 1 through 9, further comprising an optical fiber connector coupled to the substrate.

Aspect 11: A device comprising a substrate; an opto-electronic integrated device coupled to the substrate; and a group of integrated devices comprising a first integrated device; a first encapsulation layer at least partially encapsulating the first integrated device; a second integrated device coupled to the first integrated device, wherein the second integrated device vertically overlaps with the first integrated device; and a second encapsulation layer at least partially encapsulating the second integrated device.

Aspect 12: The device of aspect 11, wherein the opto-electronic integrated device is located at least partially in the substrate.

Aspect 13: The device of aspects 11 through 12, wherein the first integrated device comprises a first front side and a first back side, wherein the second integrated device comprises a second front side and a second back side, and wherein the first front side of the first integrated device is coupled to the second front side of the first integrated device.

Aspect 14: The device of aspects 11 through 13, wherein the first integrated device comprises a first plurality of through substrate vias, and wherein the second integrated device comprises a second plurality of through substrate vias.

Aspect 15: The device of aspects 11 through 14, further comprising a plurality of through encapsulation layer vias that extend through the first encapsulation layer and the second encapsulation layer.

Aspect 16: The device of aspect 15, further comprising a patch substrate coupled to the group of integrated devices through a plurality of solder interconnects.

Aspect 17: The device of aspects 11 through 16, wherein the group of integrated devices further comprises a third integrated device located at least partially in the first encapsulation layer; and a fourth integrated device located at least partially in the second encapsulation layer, wherein the fourth integrated device vertically overlaps with the third integrated device.

Aspect 18: The device of aspect 17, wherein the group of integrated devices further comprises a fifth integrated device located at least in the second encapsulation layer, wherein the fifth integrated device vertically overlaps with the first integrated device.

Aspect 19: The device of aspect 18, wherein the third integrated device comprises a third plurality of through substrate vias, wherein the fourth integrated device comprises a fourth plurality of through substrate vias, and wherein the fifth integrated device comprises a fifth plurality of through substrate vias.

Aspect 20: The device of aspects 11 through 19, further comprising an optical fiber connector coupled to the substrate.

Aspect 21: The device of aspects 11 through 20, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 22: The device of aspects 1 through 10, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the aspects. As such, the present teachings can be readily applied to other types of apparatuses and many alternatives, modifications, and variations will be apparent to those skilled in the art.

1. A device comprising:
a substrate;
an opto-electronic integrated device coupled to the substrate;
a first integrated device coupled to the substrate through a first plurality of solder interconnects; and
a second integrated device coupled to the first integrated device through a second plurality of solder interconnects.

2. The device of claim 1, wherein the opto-electronic integrated device is located at least partially in the substrate.

3. The device of claim 1,
wherein the first integrated device comprises a front side and a back side, and
wherein the back side of the first integrated device is coupled to the substrate through the first plurality of solder interconnects.

4. The device of claim 3, wherein the second integrated device is coupled to the front side of the first integrated device through the second plurality of solder interconnects.

5. The device of claim 1, further comprising:
a third integrated device coupled to the first integrated device through a third plurality of solder interconnects; and
a fourth integrated device coupled to the first integrated device through a fourth plurality of solder interconnects.

6. The device of claim 5,
wherein the second integrated device comprises a low noise amplifier,
wherein the third integrated device comprises a filter, and
wherein the fourth integrated device comprises a power amplifier.

7. The device of claim 1, wherein the second integrated device is configured to be electrically coupled to the opto-electronic integrated device through the first integrated device and the substrate.

8. The device of claim 1,
wherein the opto-electronic integrated device is configured to convert a first optical beam into at least one first electrical signal, and
wherein the opto-electronic integrated device is further configured to convert at least one second electrical signal into a second optical beam.

9. The device of claim 1, further comprises a plurality of lenses coupled to the opto-electronic integrated device.

10. The device of claim 1, further comprising an optical fiber connector coupled to the substrate.

11. A device comprising:
a substrate;
an opto-electronic integrated device coupled to the substrate; and
a group of integrated devices comprising:
a first integrated device;
a first encapsulation layer at least partially encapsulating the first integrated device;
a second integrated device coupled to the first integrated device, wherein the second integrated device vertically overlaps with the first integrated device; and
a second encapsulation layer at least partially encapsulating the second integrated device.

12. The device of claim 11, wherein the opto-electronic integrated device is located at least partially in the substrate.

13. The device of claim 11,
wherein the first integrated device comprises a first front side and a first back side,
wherein the second integrated device comprises a second front side and a second back side, and
wherein the first front side of the first integrated device is coupled to the second front side of the first integrated device.

14. The device of claim 11,
wherein the first integrated device comprises a first plurality of through substrate vias, and
wherein the second integrated device comprises a second plurality of through substrate vias.

15. The device of claim 11, further comprising a plurality of through encapsulation layer vias that extend through the first encapsulation layer and the second encapsulation layer.

16. The device of claim 15, further comprising a patch substrate coupled to the group of integrated devices through a plurality of solder interconnects.

17. The device of claim 11, wherein the group of integrated devices further comprises:
a third integrated device located at least partially in the first encapsulation layer; and
a fourth integrated device located at least partially in the second encapsulation layer, wherein the fourth integrated device vertically overlaps with the third integrated device.

18. The device of claim 17, wherein the group of integrated devices further comprises a fifth integrated device located at least in the second encapsulation layer, wherein the fifth integrated device vertically overlaps with the first integrated device.

19. The device of claim 18,
wherein the third integrated device comprises a third plurality of through substrate vias,
wherein the fourth integrated device comprises a fourth plurality of through substrate vias, and
wherein the fifth integrated device comprises a fifth plurality of through substrate vias.

20. The device of claim 11, further comprising an optical fiber connector coupled to the substrate.
